(19) United States
(12) Patent Application Publication
(10) Pub. No.: US 2008/0315878 A1
(43) Pub. Date: Dec. 25, 2008

(54) Actively Shielded Gradient Coil System Comprising Additional Additional Eddy Current Shield System

(75) Inventor: Cornelis Leonardus Gerardus Ham, Eindhoven (NL)

Correspondence Address: PHILIPS INTELLECTUAL PROPERTY & STANDARDS, 595 MINER ROAD, CLEVELAND, OH, 44143, US

(73) Assignee: KONINKLIJKE PHILIPS ELECTRONICS NV, Eindhoven (NL)

(21) Appl. No.: 10/595,922

(22) PCT Filed: Nov. 18, 2004
(86) PCT No.: PCT/IB04/52478

§ 371 Date: May 19, 2006

(30) Foreign Application Priority Data
Nov. 25, 2003 (EP) 03104350.8

(51) Int. Cl. G01R 33/385

(52) U.S. Cl. 324/318

(57) ABSTRACT

The present invention relates to a magnetic resonance imaging (MRI) system. The basic components of a MRI system are the main magnet system, the gradient system, the RF system and the signal processing system. The gradient system comprises normally three orthogonal primary coils and three orthogonal shield coils. The shield coils of the gradient system are usually designed to minimize the generation of eddy currents within the main magnet system. However, such a gradient system designed to minimize the generation of eddy currents is not optimal with respect to mechanical vibrations inside the gradient system. It is also possible to design the shield coils of the gradient system in a way to minimize mechanical vibrations inside the gradient system. However, such a gradient system is not optimal with respect to the minimization of eddy currents. The present invention provides a magnetic resonance imaging system, comprising at least: a main magnet system; a gradient system, said gradient system comprising primary coil-like elements and shield coil-like elements, said shield coil-like elements being designed to provide Lorentz force compensation for the primary coil-like elements thereby minimizing, preferably eliminating, mechanical vibrations inside the gradient system; and an eddy current shield system positioned between said main magnet system and said gradient system, said eddy current shield system being mechanically decoupled from the main magnet system and/or the gradient system.

The present invention relates to a magnetic resonance imaging system, comprising at least a main magnet system for generating a steady magnetic field in a measuring space of the magnetic resonance imaging system, a gradient system for generating a magnetic gradient field in said measuring space, said gradient system comprising primary coil-like elements and shield coil-like elements, said shield coil-like elements being designed to provide force compensation for the primary coil-like elements thereby minimizing, preferably eliminating, mechanical vibrations and/or noise inside the gradient system.

The basic components of a magnetic resonance imaging (MRI) system are the main magnet system, the gradient system, the RF system and the signal processing system. The main magnet system comprises a bore hole defining a measuring space and enabling the entry of an object to be analyzed by the MRI system. The main magnet system generates a strong uniform static field for polarization of nuclear spins in the object to be analyzed. The gradient system is designed to produce time-varying magnetic fields of controlled spatial non-uniformity. The gradient system is a crucial part of the MRI system because gradient fields are essential for signal localization. The RF system mainly consists of a transmitter coil and a receiver coil, wherein the transmitter coil is capable of generating a rotating magnetic field for excitation of a spin system, and wherein the receiver coil converts a processing magnetization into electrical signals. The signal processing system generates images on the basis of the electrical signals.

The gradient system comprises normally three orthogonal primary coil-like elements, namely a so-called X, Y and Z primary coil. The X, Y and Z nomenclature refers to the imaginary orthogonal axes used in describing MRI systems, wherein the Z axis is an axis co-axial with the axis of the bore hole of the main magnet system, wherein the X axis is the vertical axis extending from the center of the magnetic field, and wherein the Y axis is the corresponding horizontal axis orthogonal to the Z axis and the X axis. In addition to the three primary coil-like elements a gradient system may also comprise three orthogonal shield coil-like elements, namely a so-called X, Y and Z shield coil.

The shield coil-like elements of the gradient system are usually designed to minimize the stray field of the primary coil-like elements directed radially outward from the gradient system, thereby minimizing the generation or induction of eddy currents within the main magnet system. Such a gradient system can be called “eddy current optimized” gradient system. However, such a gradient system designed to minimize or eliminate the generation or induction of eddy currents within the main magnet system is not optimal with respect to mechanical vibrations and/or noise inside the gradient system, because Lorentz forces exerted on the shield coil-like elements are smaller than Lorentz forces exerted on the primary coil-like elements resulting only in a partial compensation of the Lorentz forces.

It is also possible to design the shield coil-like elements of the gradient system in a way to provide force compensation of the Lorentz forces for the primary coil-like elements thereby minimizing, preferably eliminating, mechanical vibrations and/or noise inside the gradient system. Such a gradient system can be called “Lorentz force optimized” gradient system. However, such a gradient system designed to minimize or eliminate mechanical vibrations and/or noise inside the gradient system is not optimal with respect to the minimization or elimination of eddy current generation or induction within the main magnet system.

The prior art document U.S. Pat. No. 6,147,494 discloses a magnetic resonance imaging (MRI) system comprising a “Lorentz force optimized” gradient system. In the system known from U.S. Pat. No. 6,147,494 eddy currents are induced by the gradient system in the inner radiation shield of the main magnet system. The inner radiation shield has a large time constant for the decay of the eddy currents. The vibrations resulting from these eddy currents do not lead to noise, since the radiation shield is placed in a vacuum. The implementation of this solution requires a magnet with a non-conducting bore, which is expensive. Furthermore, the eddy currents lead to an undesired temperature increase of the main magnet system, which increases boil-off of the cryogenic fluid used in the main magnet system.

It should be noted that the terms “coil” and “coil-like element” used within this patent application should cover all types of coils, e.g. saddle-shaped coils, folded coils, asymmetric coils being asymmetric in front/rear direction and/or top/down direction and all other types of coils.

It is an object of the invention to provide a magnetic resonance imaging system of the kind mentioned in the opening paragraph which comprises a “Lorentz force optimized” gradient system, but which does not have the disadvantages of the known magnetic resonance imaging system.

In order to achieve this object, a magnetic resonance imaging system in accordance with the invention comprises at least: a main magnet system for generating a steady magnetic field in a measuring space of the magnetic resonance imaging system; a gradient system for generating a magnetic gradient field in said measuring space, said gradient system comprising primary coil-like elements and shield coil-like elements, said shield coil-like elements being designed to provide Lorentz force compensation for the primary coil-like elements thereby minimizing, preferably eliminating, mechanical vibrations and/or noise inside the gradient system; and an eddy current shield system positioned between said main magnet system and said gradient system, said eddy current shield system being mechanically decoupled from the main magnet system and/or the gradient system. In accordance with a preferred embodiment of the invention the eddy current shield system comprises a set of active elements, e.g. shield coil-like elements, or at least one passive element, e.g. a conductive cylinder, or a combination of at least one active and at least one passive element.

In accordance with a further improved, preferred embodiment of the invention the eddy current shield system is designed as a constrained layer structure and/or as a perforated structure.

Preferably, a constrained layer structure is provided by an eddy current shield system comprising a set of shield coil-like elements positioned on at least two carrier tubes, wherein a visco-elastic layer is positioned between the at least two carrier tubes, and wherein the shield coil-like elements are attached to the outer carrier tube. Alternatively, the constrained layer structure could also be provided by an eddy current shield system comprising at least two conductive tubes with a visco-elastic layer positioned between the at least two conductive tubes.

Preferably, a perforated structure is provided by an eddy current shield system comprising at least one conductive tube, wherein the or each conductive tube comprises holes directed in radial direction.

In the following description, embodiments of a magnetic resonance imaging system in accordance with the invention will be described in more detail with reference to the Figures, in which:

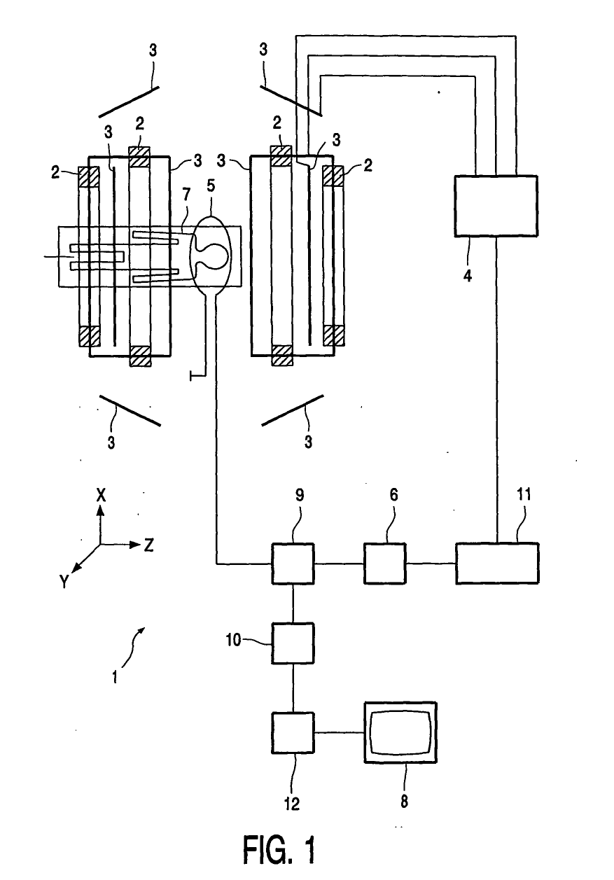

FIG. 1 shows a MRI system according to the prior art;

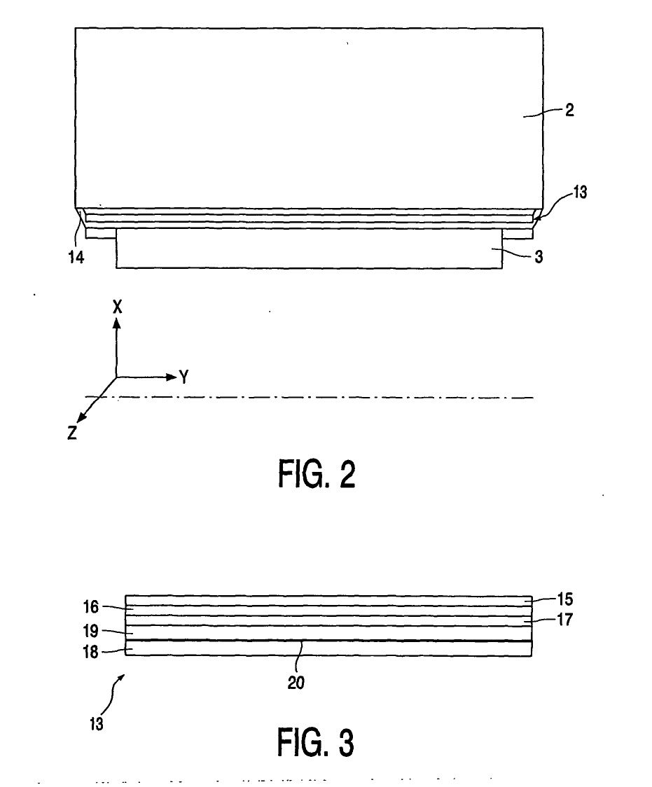

FIG. 2 shows a partial cross-sectional view through a MRI system according to the present invention;

FIG. 3 shows a cross-sectional view of an eddy current shield system of a MRI system according to a first embodiment of the present invention;

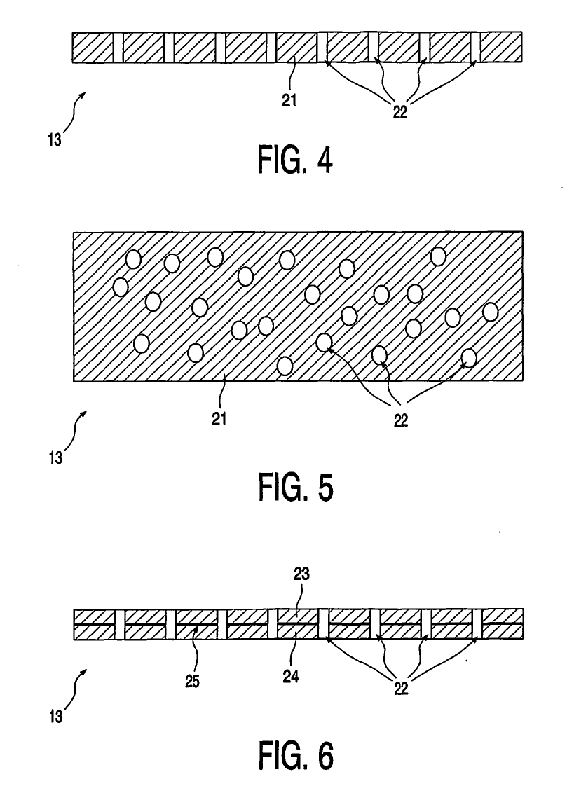

FIG. 4 shows a cross-sectional view of an eddy current shield system of a MRI system according to a second embodiment of the present invention;

FIG. 5 shows a top view of the eddy current shield system of FIG. 4; and

FIG. 6 shows a cross-sectional view of an eddy current shield system of a MRI system according to a third embodiment of the present invention.

FIG. 1 shows a magnetic resonance imaging (MRI) system 1 known from the prior art which includes a main magnet system 2 for generating a steady magnetic field, and also several gradient coils providing a gradient system 3 for generating additional magnetic fields having a gradient in the X, Y, Z directions. The Z direction of the coordinate system shown corresponds to the direction of the steady magnetic field in the main magnet system 2 by convention. The Z axis is an axis co-axial with the axis of a bore hole of the main magnet system 2, wherein the X axis is the vertical axis extending from the center of the magnetic field, and wherein the Y axis is the corresponding horizontal axis orthogonal to the Z axis and the X axis.

The gradient coils of the gradient system 3 are fed by a power supply unit 4. An RF transmitter coil 5 serves to generate RF magnetic fields and is connected to an RF transmitter and modulator 6.

A receiver coil is used to receive the magnetic resonance signal generated by the RF field in the object 7 to be examined, for example a human or animal body. This coil may be the same coil as the RF transmitter coil 5. Furthermore, the main magnet system 2 encloses an examination space which is large enough to accommodate a part of the body 7 to be examined. The RF coil 5 is arranged around or on the part of the body 7 to be examined in this examination space. The RF transmitter coil 5 is connected to a signal amplifier and demodulation unit 10 via a transmission/reception circuit 9.

The control unit 11 controls the RF transmitter and modulator 6 and the power supply unit 4 so as to generate special pulse sequences which contain RF pulses and gradients. The phase and amplitude obtained from the demodulation unit 10 are applied to a processing unit 12. The processing unit 12 processes the presented signal values so as to form an image by transformation. This image can be visualized, for example by means of a monitor 8.

According to the present invention the gradient system 3 of the magnetic resonance imaging system 1 comprises three orthogonal primary coils, namely an X primary coil, a Y primary coil and a Z primary coil, and in addition three orthogonal shield coils, namely an X shield coil, a Y shield coil and a Z shield coil. The three orthogonal primary coils and the three orthogonal shield coils of the gradient system 3 are not shown in the drawings. The shield coils of the gradient system 3 are designed to provide Lorentz force compensation within the gradient system 3. In order to provide a gradient system 3 with Lorentz force compensation, the number of windings and the position of said windings of the three orthogonal shield coils of the gradient system 3 are adapted to the number of windings and the position of said windings of the three orthogonal primary coils of said gradient system 3. With such a Lorentz force compensating gradient system 3 the mechanical vibrations and noise within the gradient system 3 can be minimized, preferably eliminated.

Such a gradient system 3 with shield coils being designed to provide Lorentz force compensation is not optimal as regards shielding properties to shield the stray field coming from the primary coils and to minimize the generation or induction of eddy currents within the main magnet system 2.

In order to provide in addition to the Lorentz force compensation properties also good properties as regards minimized eddy currents, the magnetic resonance imaging system according to the present invention comprises an eddy current shield system 13. According to FIG. 2 the eddy current shield system 13 is positioned between the main magnet system 2 and the gradient system 3, namely between the housing of the main magnet system 2 and the gradient system 3. The housing is called cryostat. So, according to the present invention the eddy current shield system 13 is positioned outside the cryostat and between the cryostat and the gradient system 3. The eddy current shield system 13 is positioned within a space 14 between the main magnet system 2, i.e. the cryostat, and the gradient system 3, said space 14 being closed. Preferably, the space 14 is vacuum-filled.

The eddy current shield system 13 is preferably connected to the main magnet system 2 but mechanically decoupled from the main magnet system 2 and also from the gradient system 3. It is noted that the expression “mechanically decoupled from” is to be taken to mean that the eddy current shield system 13 is connected to the main magnet system 2 and/or to the gradient system 3 by means of connecting means, or comprises damping means, which substantially reduce or substantially prevent the transmission of mechanical vibrations from the eddy current shield system 13 to the main magnet system 2 and/or to the gradient system 3. Examples of such connecting means and damping means will be described in more detail hereafter. The eddy current shield system 13 has the function to shield the main magnet system 2 with respect to the stray fields directed radially outward from the gradient system 3 by the primary coils of the gradient system 3 radially outward of the gradient system 3. For this purpose, Lorentz forces will be exerted in the eddy current shield system 13 and this will cause vibrations within the eddy current shield system 13. Due to the fact that the eddy current shield system 13 is mechanically decoupled from the main magnet system 2 and the gradient system 3, the effect of these vibrations within the eddy current shield system 13 is minimized. A further reduction of the effects of the vibrations within the eddy current shield system 13 can be provided by the fact that the eddy current shield system 13 is positioned within the closed space 14, which is preferably vacuum-filled.

A first preferred embodiment of the eddy current shield system 13 is shown in FIG. 3. The eddy current shield system 13 according to FIG. 3 comprises a set of active elements, that is a set of three additional shield coils, namely an additional X shield coil 15, an additional Y shield coil 16 and an additional Z shield coil 17. The three additional, orthogonal shield coils 15, 16 and 17 are positioned on two carrier tubes, namely an inner carrier tube 18 and an outer carrier tube 19. Between said two carrier tubes 18 and 19 there is positioned a visco-elastic layer 20. Such a visco-elastic layer with viscous properties provides the mechanical damping of the structure and therefore a reduction of the vibration level. It can be taken from FIG. 3 that the additional Z shield coil 17 is positioned on the outer carrier tube 19, that the additional Y shield coil 16 is positioned on said additional Z shield coil 17 and that the additional X shield coil 15 is positioned on said Y shield coil 17. The eddy current shield system 13 according to FIG. 3 comprising three orthogonal shield coils 15, 16 and 17 and two carrier tubes 18 and 19 with a visco-elastic layer 20 positioned between said carrier tubes 18 and 19 provides a so-called constrained layer structure of the eddy current shield system 13. With such a constraint layer structure, the vibrations and the noise level within the eddy current shield system 13 can be further minimized.

FIGS. 4 and 5 show a further preferred embodiment of an eddy current shield system 13, wherein FIG. 4 shows a cross section and FIG. 5 shows a top view of said eddy current shield system 13. The eddy current shield system 13 according to FIGS. 4 and 5 comprises one passive element which is provided in the form of a highly conductive cylinder or tube 21. The conductive cylinder or tube 21 is preferably made from copper having a thickness of for example 5 mm. According to the embodiment shown in FIGS. 4 and 5, holes 22 are formed within said conductive tube 21, and the holes 22 extend in radial direction through the entire thickness of the conductive tube 21. The eddy current shield system 13 according to FIGS. 4 and 5 provides a so-called perforated structure. Such a perforated structure is also used to minimize the radiated noise from the eddy current shield system.

A further eddy current shield system 13 according to the present invention is shown in FIG. 6. The eddy current shield system 13 according to FIG. 6 comprises two passive elements, namely two conductive cylinders or tubes 23 and 24. Between said conductive tubes 23 and 24, which are preferably provided as copper cylinders, there is located a visco-elastic layer 25. In addition to this visco-elastic layer 25, the eddy current shield system 13 according to FIG. 6 comprises also holes 22 extending in radial direction through the two conductive tubes 23 and 24 and also through the visco-elastic layer 25. The eddy current shield system 13 according to FIG. 6 provides a combined constrained layer and perforated structure, which allows further minimization of vibrations and noise within the eddy current shield system 13.

Beyond the embodiments shown in FIGS. 3 to 6, it is also possible that an eddy current shield system combines a set of active elements in the form of additional shield coils with passive elements in the form of conductive tubes. Such a design combining active and passive elements may be designed as a constrained layer structure and/or perforated structure.

In addition, it is possible that an eddy current shield system having only active elements, such as additional shield coils, may comprise holes extending through the eddy current shield system in radial direction to further minimize or reduce the radiated noise from said eddy current shield system.

The eddy current systems 13 shown in FIGS. 3 to 6 may all comprise a support structure, which support structure connects the eddy current shield system 13 to the main magnet system 2 or the gradient system 3. It is also possible that the support structure of the eddy current shield system connects the eddy current shield system to the floor, on which the entire magnetic resonance imaging system is positioned. If the support structure connects the eddy current shield system 13 to the main magnet system 2 and/or to the gradient system 3, the support structure comprises decoupling means to provide mechanical decoupling of the eddy current shield system 13 from the main magnet system 2 and/or the gradient system 3. The decoupling means can be provided as passive means, such as strips or blocks of rubber-like material or as active means such as piezo means. It is also possible to combine active and passive decoupling means.

The magnetic resonance imaging system according to the present invention comprises a main magnet system and a gradient system, wherein the gradient system comprises primary coils and shield coils. The shield coils of the gradient system are designed to compensate Lorentz forces and to provide a vibration-free gradient system. In addition to the main magnet system and the gradient system, the magnet resonance imaging system according to the present invention comprises an eddy current shield system, which is arranged between the gradient system and the main magnet system. The eddy current system is mechanically decoupled from the gradient system and the main magnet system. The eddy current shield system may comprise active means in the form of active coils, passive means in the form of conductive cylinders, or a combination thereof. The eddy current shield system may also comprise a constrained layer structure and/or a perforation structure. The magnet resonance imaging system according to the present invention has optimized vibration and noise properties and provides the elimination of eddy current induction within the main magnet system.

According to another aspect of the present invention, a glass fiber reinforced epoxy layer is positioned between the primary coils and the shield coils of the gradient system 3. The glass fibers are preferably directed in the radial direction of the gradient system. This provides sufficient stiffness to the gradient system in the radial direction. It is also possible to use ceramic material instead of the glass fiber reinforced epoxy between the primary coils and the shield coils. It is preferred to use materials with high visco-elasticity modules (high E-modules) between the primary coils and the shield coils of the gradient system, because of the fact that materials with high E-modules result in lower noise levels of the gradient system.

### LIST OF REFERENCE NUMBERS

1 magnetic resonance imaging system
2 main magnet system
3 gradient system
4 power supply unit
5 RF transmitter coil
6 modulator
7 object
8 monitor
9 transmission/reception circuit
10 demodulation unit
11 control unit
12 processing unit
13 eddy current shield system
14 space
15 additional X shield coil
16 additional Y shield coil
17 additional Z shield coil
18 inner carrier tube
19 outer carrier tube
20 visco-elastic layer
21 conductive tube
22 hole
23 conductive tube
24 conductive tube
25 visco-elastic layer

1. A magnetic resonance imaging system, comprising at least:
a) a main magnet system for generating a steady magnetic field in a measuring space of the magnetic resonance imaging system,
b) a gradient system for generating a magnetic gradient field in said measuring space, said gradient system comprising primary coil-like elements and shield coil-like elements, said shield coil-like elements being designed to provide force compensation for the primary coil-like elements thereby reducing, mechanical vibrations and/or noise inside the gradient system,
c) an eddy current shield system positioned between said main magnet system and said gradient system, said eddy current shield system being mechanically decoupled from the main magnet system and/or the gradient system.

2. A magnetic resonance imaging system according to claim 1, wherein the eddy current shield system is positioned within a space between said main magnet system and said gradient system, said space being closed.

3. A magnetic resonance imaging system according to claim 2, wherein the eddy current shield system is positioned within a closed vacuum space.

4. A magnetic resonance imaging system according to claim 1, wherein the eddy current shield system comprises at least one active element or at least one passive element or a combination of at least one active and at least one passive element.

5. A magnetic resonance imaging system according to claim 4, wherein the eddy current shield system comprises a set of active elements, namely a set of additional shield coil-like elements.

6. A magnetic resonance imaging system according to claim 5, wherein the eddy current shield system comprises a set of three orthogonal shield coils.

7. A magnetic resonance imaging system according to claim 4, wherein the eddy current shield system comprises at least one passive element designed as a conductive tube.

8. A magnetic resonance imaging system according to claim 4, wherein the eddy current shield system comprises a set of shield coil-like elements in combination with at least one conductive tube.

9. A magnetic resonance imaging system according to claim 1, wherein the eddy current shield system comprises a support structure, wherein the support structure is connected to and mechanically decoupled from the main magnet system and/or the gradient system.

10. A magnetic resonance imaging system according to claim 9, wherein the support structure is connected to and mechanically decoupled from the main magnet system and/or the gradient system by decoupling means.

11. A magnetic resonance imaging system according to claim 10, wherein the decoupling means are designed as passive means taking the form of strips or blocks or rubber-like material and/or as active means such as piezo means.

12. A magnetic resonance imaging system according to claim 1, wherein the eddy current shield system is designed as a constrained layer structure and/or as a perforated structure.

13. A magnetic resonance imaging system according to claim 12, wherein the eddy current shield system comprises a set of shield coil-like elements positioned on at least one carrier tube, wherein the coil-like elements and the or each carrier tube are attached together providing a constrained layer structure.

14. A magnetic resonance imaging system according to claim 13, comprising two carrier tubes, wherein a visco-elastic layer is positioned between the two carrier tubes, and wherein the set of shield coil-like elements are attached to the outer carrier tube.

15. A magnetic resonance imaging system according to claim 12, wherein the eddy current shield system comprises at least one conductive tube, wherein the or each conductive tube comprises holes directed in radial direction providing a perforated structure.

16. A magnetic resonance imaging system according to claim 15, comprising at least two conductive tubes with a visco-elastic layer positioned between the at least two conductive tubes and with holes directed in radial direction providing a perforated and constrained layer structure.
